(19) United States
(12) Patent Application Publication
(10) Pub. No.: US 2018/0171467 A1
(43) Pub. Date: Jun. 21, 2018

(54) Method of Manufacturing Semiconductor Device, Substrate Processing Apparatus and Non-Transitory Computer-Readable Recording Medium

(71) Applicant: Hitachi Kokusai Electric Inc., Tokyo (JP)

(72) Inventors: Hiroki HATTA, Toyama (JP); Hideki HORITA, Toyama (JP)

(21) Appl. No.: 15/849,271

(22) Filed: Dec. 20, 2017

(30) Foreign Application Priority Data
Dec. 20, 2016 (JP) 2016-246591

(51) Int. Cl. C23C 14/54; G01B 21/08; C23C 16/52; H01L 21/02; H01L 21/66; B05D 1/00; C23C 16/34

(52) U.S. Cl. CPC C23C 14/542; G01B 21/085; C23C 16/52; H01L 21/02334; G06F 17/50; B05D 1/60; C23C 16/345; H01L 21/022; H01L 22/12

(57) ABSTRACT

A technique capable of controlling a film thickness distribution formed on a surface of a substrate includes: forming a film on a substrate by performing a cycle a predetermined number of times, the cycle including: (a) supplying a source to the substrate accommodated in a process chamber; (b) exhausting the source from the process chamber; (c) supplying a reactant to the substrate accommodated in the process chamber; and (d) exhausting the reactant from the process chamber, wherein (a) through (d) are performed non-simultaneously, and the cycle further includes at least one of: (e) starting a next step with the source remaining in a center portion of a substrate surface after a first predetermined time elapses from a start of (b); and (f) starting a next step with the reactant remaining in the center portion of the substrate's surface after a second predetermined time elapses from a start of (d).

### CROSS REFERENCE TO RELATED APPLICATIONS

This application claims foreign priority under 35 U.S.C. § 119(a)-(d) to Japanese Patent Application No. 2016-246591 filed on Dec. 20, 2016, the entire contents of which are hereby incorporated by reference.

### TECHNICAL FIELD

The present disclosure relates to a method of manufacturing a semiconductor device, a substrate processing apparatus and a non-transitory computer-readable recording medium.

### BACKGROUND

The process of manufacturing a semiconductor device may include, for example, a substrate processing of forming a film on a substrate by alternately supplying a source and a reactant to the substrate.

### SUMMARY

Described herein is a technique capable of controlling a thickness distribution of a film formed on a surface of a substrate.

According to one aspect of the technique described herein, there is provided a method of manufacturing a semiconductor device, including: forming a film on a substrate by performing a cycle a predetermined number of times, the cycle including: (a) supplying a source to the substrate accommodated in a process chamber; (b) exhausting the source from the process chamber; (c) supplying a reactant to the substrate accommodated in the process chamber; and (d) exhausting the reactant from the process chamber, wherein (a) through (d) are performed non-simultaneously, and the cycle further includes at least one of: (e) starting a next step with the source remaining in a center portion of a surface of the substrate after a first predetermined time elapses from a start of (b); and (f) starting a next step with the reactant remaining in the center portion of the surface of the substrate after a second predetermined time elapses from a start of (d).

### BRIEF DESCRIPTION OF THE DRAWINGS

FIG. 1 schematically illustrates a vertical cross-section of a vertical type processing furnace of a substrate processing apparatus preferably used in an embodiment described herein.

FIG. 2 schematically illustrates a cross-section taken along the line A-A of the vertical type processing furnace of the substrate processing apparatus shown in FIG. 1.

FIG. 3 is a block diagram schematically illustrating a configuration of a controller and components controlled by the controller of the substrate processing apparatus according to the embodiment.

FIG. 4 schematically illustrates a film-forming sequence according to the embodiment.

FIG. 5A illustrates a wafer at the beginning of a step A1 of a first cycle, FIG. 5B illustrates the wafer supplied with HCDS gas over the entire surface thereof by performing the step A1 of the first cycle, FIG. 5C illustrates the wafer with residual HCDS at the center portion of the surface thereof after performing a step A2 of the first cycle, FIG. 5D illustrates the wafer at the beginning of a step B1 of the first cycle with the residual HCDS at the center portion of the surface thereof, FIG. 5E illustrates the wafer supplied with NH₃ gas over the entire surface thereof by performing the step B1 of the first cycle, FIG. 5F illustrates the wafer with residual NH₃ at the center portion of the surface thereof after performing the step B2 of the first cycle, FIG. 5G illustrates the wafer at the beginning of a step A1 of a second cycle with the residual NH₃ at the center portion of the surface thereof, and FIG. 5H illustrates the wafer supplied with HCDS gas over the entire surface thereof by performing the step A1 of the second cycle.

### DETAILED DESCRIPTION

### Embodiment

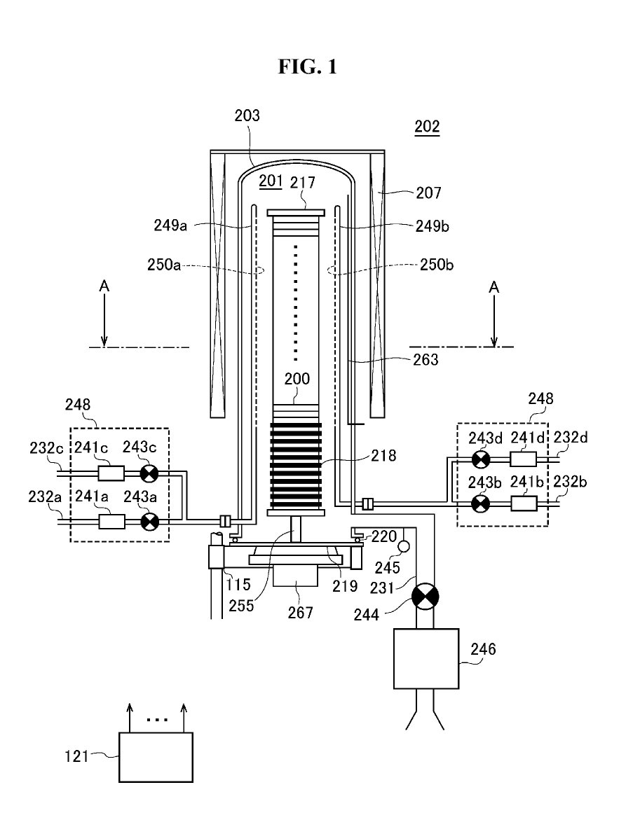

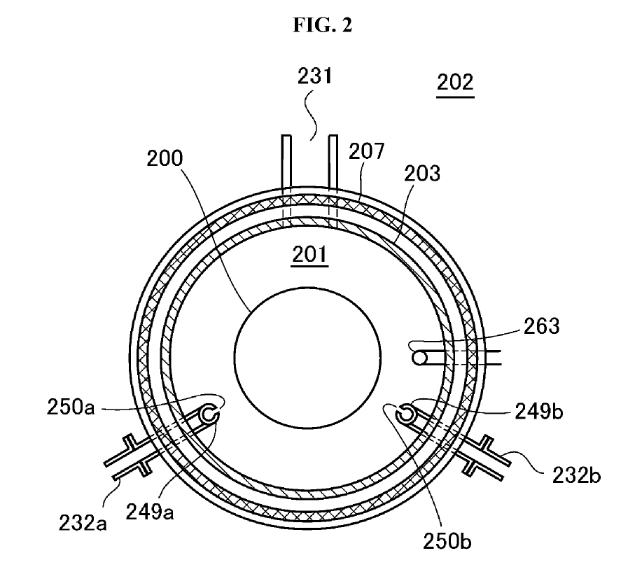

Hereinafter, an embodiment will be described with reference to FIGS. 1 through 3.

### (1) CONFIGURATION OF SUBSTRATE PROCESSING APPARATUS

As illustrated in FIG. 1, a processing furnace 202 includes a heater 207 serving as a heating apparatus (heating mechanism). The heater 207 is cylindrical, and vertically installed while being supported by a support plate (not shown). The heater 207 also functions as an activation mechanism (excitation unit) for activating (exciting) a gas by heat.

### Process Chamber

A reaction tube 203 is provided in the heater 207 concentrically with the heater 207. The reaction tube 203 is made of a heat-resistant material such as quartz (SiO₂) and silicon carbide (SiC), and is cylindrical with a closed upper end and an open lower end. A process chamber 201 is provided in the hollow cylindrical portion of the reaction tube 203. The process chamber 201 is capable of accommodating wafers (substrates) 200.

Nozzles 249a and 249b are provided in the process chamber 201 through sidewalls of the reaction tube 203. Gas supply pipes 232a and 232b are connected to the nozzles 249a and 249b, respectively.

MFCs (Mass Flow Controllers) 241a and 241b serving as flow rate controllers (flow rate control units) and valves 243a and 243b serving as opening/closing valves are installed in order at the gas supply pipes 232a and 232b from the upstream sides to the downstream sides of the gas supply pipes 232a and 232b, respectively. Gas supply pipes 232c and 232d for supplying an inert gas are connected to the downstream sides of the valves 243a and 243b installed at the gas supply pipes 232a and 232b, respectively. MFCs 241c and 241d and valves 243c and 243d are installed in order at the gas supply pipes 232c and 232d from the upstream sides to the downstream sides of the gas supply pipes 232c and 232d, respectively.

As shown in FIG. 2, the nozzles 249a and 249b are provided in an annular space between the inner wall of the reaction tube 203 and the wafers 200, and extend from the bottom to the top of the inner wall of the reaction tube 203 along the stacking direction of the wafers 200. That is, the nozzles 249a and 249b extend in a space that horizontally surrounds a wafer arrangement region where the wafers 200 are arranged along the stacking direction of the wafers 200. A plurality of gas supply holes 250a and a plurality of gas supply holes 250b for supplying gases are provided at side surfaces of the nozzles 249a and 249b, respectively. The gas supply holes 250a and 250b are open toward the center of the reaction tube 203 to supply gases toward the wafers 200. The gas supply holes 250a and 250b are provided from the lower portion to the upper portion of the reaction tube 203.

A source (source gas) such as a halosilane-based gas containing silicon (Si: first element) and halogen element is supplied to the process chamber 201 through the MFC 241a and the valve 243a which are provided at the gas supply pipe 232a and the nozzle 249a. The source includes a source in gaseous state under normal temperature and pressure and also a gas obtained by evaporating a liquid source under normal temperature and pressure. The halogen element includes, for example, chlorine (Cl), fluorine (F), bromine (Br) and iodine (I). For example, a chlorosilane-based gas containing chlorine (Cl) such as hexachlorodisilane (Si₂Cl₆, abbreviated as HCDS) gas may be used as the halosilane-based gas.

A reactant (reactive gas) such as a gas containing nitrogen (N: second element), which is a nitriding gas or a nitriding agent, is supplied into the process chamber 201 via the MFC 241b and the valve 243b which are provided at the gas supply pipe 232b and the nozzle 249b. A hydrogen nitride-based gas such as ammonia (NH₃) gas may be used as the nitriding gas.

The inert gas is supplied into the process chamber 201 through the MFCs 241c and 241d and the valves 243c and 243d provided at the gas supply pipes 232c and 232d, the gas supply pipes 232a and 232b and the nozzles 249a and 249b. For example, nitrogen (N₂) gas may be used as the inert gas.

A source supply system is constituted by the gas supply pipe 232a, the MFC 241a and the valve 243a. A reactant supply system is constituted by the gas supply pipe 232b, the MFC 241b the valve 243b. An inert gas supply system (purge gas supply system) is constituted by the gas supply pipes 232c and 232d, the MFCs 241c and 241d and the valves 243c and 243d.

Any one or all of the above-described supply systems may be embodied as an integrated gas supply system 248 in which the components such as the valves 243a through 243d or the MFCs 241a through 241d are integrated. The integrated gas supply system 248 is connected to the respective gas supply pipes 232a through 232d. An operation of the integrated gas supply system 248 to supply various gases to the gas supply pipes 232a through 232d, for example, operations such as an operation of opening/closing the valves 243a through 243d and an operation of adjusting a flow rate through the MFCs 241a through 241d may be controlled by a controller 121 described later. The integrated gas supply system 248 may be embodied as an integrated unit having an all-in-one or divided structure. The components of the integrated gas supply system 248, such as the gas supply pipes 232a through 232d, may be attached/detached on a basis of the integrated unit. Operations such as maintenance, exchange and addition of the integrated gas supply system 248 may be performed on a basis of the integrated unit.

The exhaust pipe 231 for exhausting the inner atmosphere of the process chamber 201 is provided at the reaction tube 203. A vacuum pump 246 serving as a vacuum exhaust device is connected to the exhaust pipe 231 through a pressure sensor 245 and an APC (Automatic Pressure Controller) valve 244. The pressure sensor 245 serves as a pressure detector (pressure detecting unit) to detect the inner pressure of the process chamber 201, and the APC valve 244 serves as a pressure controller (pressure adjusting unit). With the vacuum pump 246 in operation, the APC valve 244 may be opened/closed to vacuum-exhaust the process chamber 201 or stop the vacuum exhaust. With the vacuum pump 246 in operation, the opening degree of the APC valve 244 may be adjusted based on the pressure detected by the pressure sensor 245, in order to control the inner pressure of the process chamber 201. An exhaust system is constituted by the exhaust pipe 231, the APC valve 244 and the pressure sensor 245. The exhaust system may further include the vacuum pump 246.

A seal cap (furnace opening cover) 219 capable of airtightly sealing the lower end opening of the reaction tube 203 is provided under the reaction tube 203. The seal cap 219 is made of metal such as SUS, and is a disk-shaped. An O-ring 220 serving as a sealing member is provided on the upper surface of the seal cap 219 and is in contact with the lower end of the reaction tube 203. A rotating mechanism 267 to rotate a boat 217 described later is provided under the seal cap 219. A rotating shaft 255 of the rotating mechanism 267 is connected to the boat 217 through the seal cap 219. As the rotating mechanism 267 rotates the boat 217, the wafers 200 are rotated. The seal cap 219 may be moved up and down by a boat elevator (elevating mechanism) 115 provided outside the reaction tube 203. When the seal cap 219 is moved up and down by the boat elevator 115, the boat 217 may be loaded into the process chamber 201 or unloaded from the process chamber 201. The boat elevator 115 serves as a transfer device (transfer mechanism) that loads the boat 217 or the wafers 200 into the process chamber 201 or unloads the boat 217 or the wafers 200 from the process chamber 201.

The boat (substrate retainer) 217 supports concentrically aligned wafers 200 (e.g. 25 to 200 wafers 200) in vertical direction while the wafers 200 are in horizontal orientation. That is, the boat 217 supports, in multiple stages, concentrically arranged the wafers 200 with a predetermined interval therebetween. The boat 217 is made of a heat-resistant material such as quartz and SiC. An insulating plate 218 is made of a heat-resistant material such as quartz and SiC, and provided under the boat 217 in multiple stages.

A temperature sensor (temperature detector) 263 is provided in the reaction tube 203. The energization state of the heater 207 is controlled based on the temperature detected by the temperature sensor 263 such that the inner temperature of the process chamber 201 has a desired temperature distribution. The temperature sensor 263 is provided along the inner wall of the reaction tube 203.

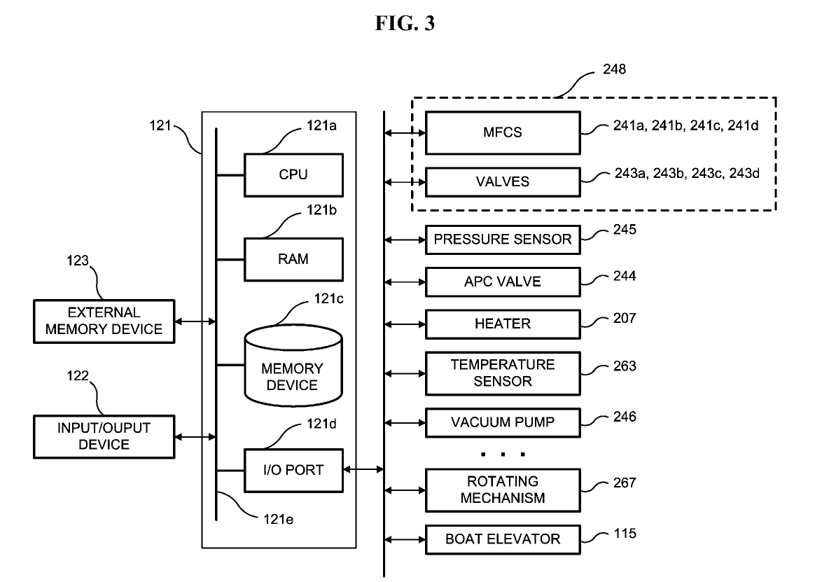

As shown in FIG. 3, the controller 121 serving as a control unit (control means) is embodied by a computer including a CPU (Central Processing Unit) 121a, a RAM (Random Access Memory) 121b, a memory device 121c and an I/O port 121d. The RAM 121b, the memory device 121c and the I/O port 121d may exchange data with the CPU 121a through an internal bus 121e. For example, an I/O device 122 such as a touch panel is connected to the controller 121.

The memory device 121c is embodied by components such as a flash memory and HDD (Hard Disk Drive). A control program for controlling the operation of the substrate processing apparatus or a process recipe containing information on the sequence and conditions of a substrate processing described later is readably stored in the memory device 121c. The process recipe is obtained by combining steps of the substrate processing described later such that the controller 121 may execute the steps to acquire a predetermine result, and functions as a program. Hereafter, the process recipe and the control program are collectively referred to as a program. The process recipe is simply referred to as a recipe. In this specification, “program” may indicate only the recipe, indicate only the control program, or indicate both of them. The RAM 121b is a work area where a program or data read by the CPU 121a is temporarily stored.

The I/O port 121d is connected to the above-described components such as the MFCs 241a through 241d, the valves 243a through 243d, the pressure sensor 245, the APC valve 244, the vacuum pump 246, the temperature sensor 263, the heater 207, the rotating mechanism 267 and the boat elevator 115.

The CPU 121a is configured to read a control program from the memory device 121c and execute the read control program. Furthermore, the CPU 121a is configured to read a recipe from the memory device 121c according to an operation command inputted from the I/O device 122. According to the contents of the read recipe, the CPU 121a may be configured to control various operations such as flow rate adjusting operations for various gases by the MFCs 241a through 241d, opening/closing operations of the valves 243a through 243d, an opening/closing operation of the APC valve 244, a pressure adjusting operation by the APC valve 244 based on the pressure sensor 245, a start and stop of the vacuum pump 246, a temperature adjusting operation of the heater 207 based on the temperature sensor 263, a rotation operation and rotation speed adjusting operation of the boat 217 by the rotating mechanism 267, and an elevating operation of the boat 217 by the boat elevator 115.

The controller 121 may be embodied by installing the above-described program stored in an external memory device 123 into a computer, the external memory device 123 including a magnetic disk such as a hard disk, an optical disk such as CD, a magneto-optical disk such as MO, and a semiconductor memory such as a USB memory. The memory device 121c or the external memory device 123 may be embodied by a non-transitory computer readable recording medium. Hereafter, the memory device 121c and the external memory device 123 are collectively referred to as recording media. In this specification, “recording media” may indicate only the memory device 121c, indicate only the external memory device 123, and indicate both of the memory device 121c and the external memory device 123. In addition to the external memory device 123, a communication unit such as the Internet and dedicated line may be used as the unit for providing a program to a computer.

### (2) FILM-FORMING PROCESS

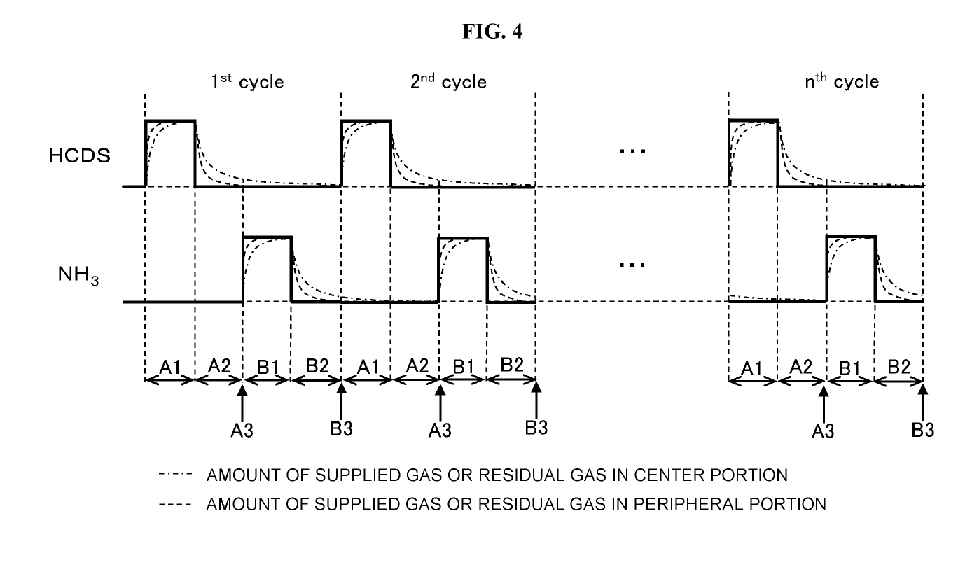

Next, an exemplary film-forming sequence of forming a silicon nitride (SiN) film on a wafer 200, which is a substrate processing for manufacturing a semiconductor device, using the above-described substrate processing apparatus will be described with reference to FIG. 4. Herein, the components of the substrate processing apparatus are controlled by the controller 121.

FIG. 4 schematically illustrates a film-forming sequence according to the embodiment. As shown in FIG. 4, a film containing silicon (Si) and nitrogen (N), i.e., a silicon nitride (SiN) film, is formed on the wafer 200 by performing a cycle a predetermined number of times. The cycle includes a step A1 of supplying HCDS gas to the wafer 200 in the process chamber; a step A2 of exhausting HCDS gas from the process chamber; a step B1 of supplying NH₃ gas to the wafer 200 in the process chamber and a step B2 of exhausting NH₃ gas from the process chamber.

The cycle further includes at least one of the steps A3 and B3. The step A3 is a time point whereat the next step (step B1) starts with HCDS gas remaining in the center portion of the surface of the wafer 200 after a predetermined time has elapsed from the start of the step A2. The step B3 is a time point whereat the next step (step A1) starts with NH₃ gas remaining in the center portion of the surface of the wafer 200 after a predetermined time has elapsed from the start of the step B2. A film-forming sequence in which the cycle includes both of the steps A3 and B3 is exemplified in FIG. 4.

An example wherein a patterned wafer having thereon an uneven structure including a concave portion and a convex portion is used will be described. The surface area of the patterned wafer is larger than that of a bare wafer without an uneven structure. Thus, a SiN film formed on the surface of the patterned wafer is likely to have a thickness distribution (referred to as “thickness distribution of the surface”) wherein the SiN film is thinner at the center portion of the surface of the wafer 200 and gradually becomes thicker toward the peripheral portion (outer circumferential portion) of the surface of the wafer 200. Such thickness distribution is referred to as “thickness distribution having thinner center.” In contrast, the thickness distribution of the SiN film formed on the patterned wafer according to the film-forming sequence shown in FIG. 4 may be a “flat thickness distribution” wherein the SiN film is flat with only a small deviation in thickness from the center portion to the peripheral portion of the wafer 200 or a “thickness distribution having thicker center” wherein the SiN film is thicker at the center portion of the surface of the wafer 200 and gradually becomes thinner toward the peripheral portion of the wafer 200.

Herein, the film-forming sequence shown in FIG. 4 according to the embodiment may be represented as follows: ‘HCDS’ indicates the execution of the step A1, ‘P₁’ indicates the execution of the steps A2 and A3, ‘NH₃’ indicates the execution of the step B1, and T2′ indicates the execution of the steps B2 and B3. Since the execution of the step A3 is the end of ‘P₁’ and also the start of ‘NH₃’, the execution of the step A3 may be included in ‘NH₃’. In addition, since the execution of the step B3 is the end of ‘P2’ and also the start of ‘HCDS’, the execution of the step B3 may be included in ‘HCDS’. The same applies to the modified examples which will be described later.

(HCDS→P₁→NH₃→P₂)×n→SiN

Herein, “wafer” may refer to “a wafer itself” or to “a wafer and a stacked structure (aggregated structure) of predetermined layers or films formed on the surface of the wafer”. That is, the wafer and the predetermined layers or films formed on the surface of the wafer may be collectively referred to as the wafer. In this specification, “surface of wafer” refers to “a surface (exposed surface) of a wafer” or to “the surface of a predetermined layer or film formed on the wafer, i.e. the top surface of the wafer as a stacked structure”. Thus, in this specification, “forming a predetermined layer (or film) on a wafer” may refer to “forming a predetermined layer (or film) on a surface of wafer itself” or to “forming a predetermined layer (or film) on a surface of a layer or film formed on the wafer”, i.e. “forming a predetermined layer (or film) on a top surface of a stacked structure”. Herein, “substrate” and “wafer” may be used as substantially the same meaning.

### Wafer Charging and Boat Loading Step

Wafers 200 are charged into the boat 217 (wafer charging). Thereafter, as shown in FIG. 1, the boat 217 charged with wafers 200 is lifted by the boat elevator 115 and loaded into the process chamber 201 (boat loading). With the boat 217 loaded, the seal cap 219 seals the lower end of the reaction tube 203 through the O-ring 220b.

### Pressure and Temperature Adjusting Step

The vacuum pump 246 vacuum-exhausts the process chamber 201 such that the inner pressure of the process chamber 201, i.e., the pressure of the space in which the wafers 200 are present is set to a desired pressure (vacuum level). At this time, the inner pressure of the process chamber 201 is measured by the pressure sensor 245, and the APC valve 244 is feedback controlled based on the measured pressure. Until at least the process for the wafers 200 is complete, the vacuum pump 246 continuously vacuum-exhausts the process chamber 201. The heater 207 heats the process chamber 201 such that the temperature of the wafers 200 in the process chamber 201 becomes a desired temperature. The energization state of the heater 207 is feedback controlled based on the temperature detected by the temperature sensor 263 such that the inner temperature of the process chamber 201 has a desired temperature distribution. Until at least the process for the wafers 200 is complete, the heater 207 continuously heats the process chamber 201. The rotating mechanism 267 starts to rotate the boat 217 and the wafers 200. Until at least the process for the wafers 200 is complete, the rotating mechanism 267 continuously rotates the boat 217 and the wafer 200.

### Film-Forming Process

Next, the film forming process is performed by performing steps A1 through A3 and B1 through B3 in order.

### Step A1

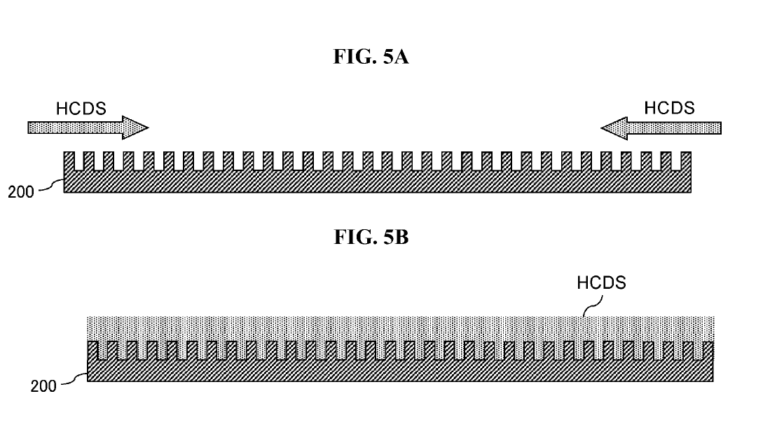

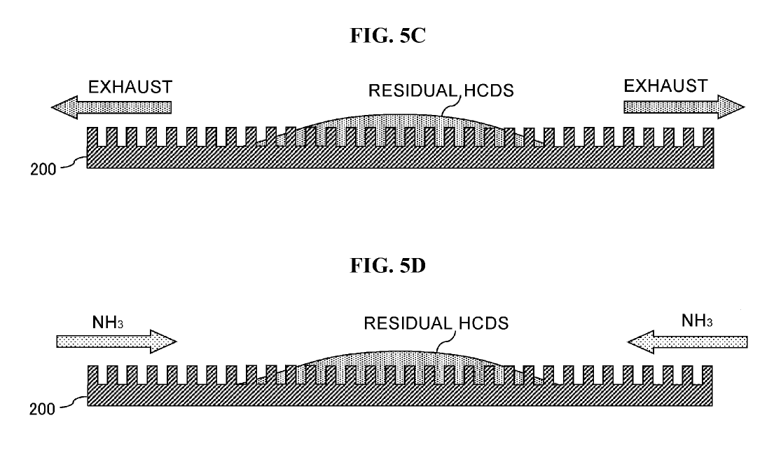

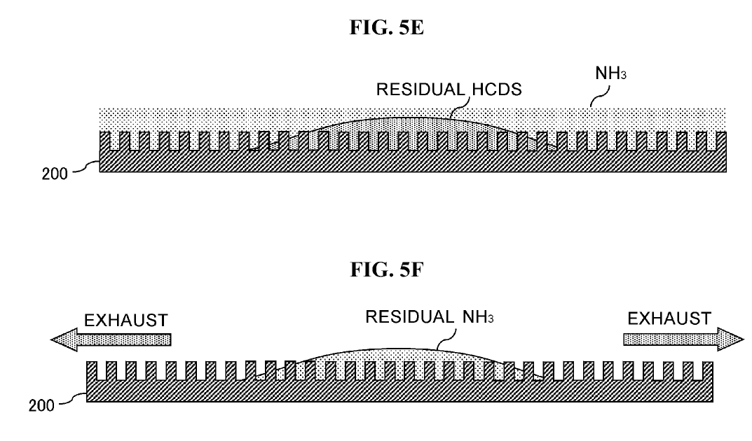

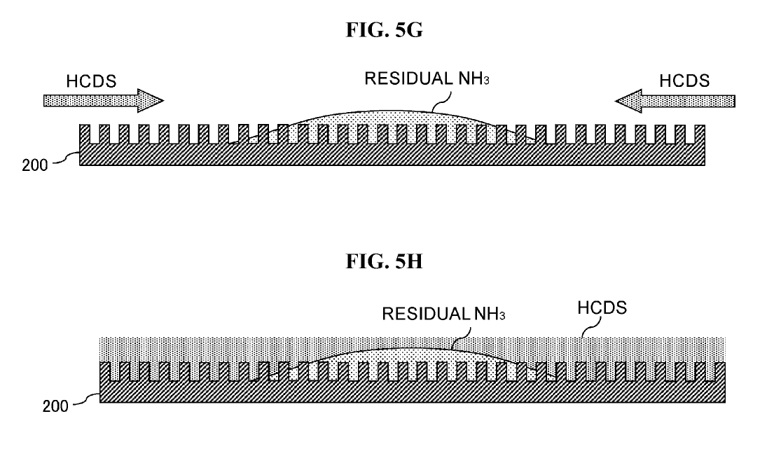

In the step A1, HCDS gas is supplied to the wafer 200 in the process chamber 201. Specifically, the valve 243a is opened to supply HCDS gas into the gas supply pipe 232a. After the flow rate of HCDS gas is adjusted by the MFC 241a, HCDS gas is supplied into the process chamber 201 through nozzle 249a and exhausted through the exhaust pipe 231. Thereby, the HCDS gas is supplied onto the wafer 200. Simultaneously, the valves 243c and 243d may be opened to supply N2 gas into the gas supply pipes 232c and 232d. After the flow rate of N2 gas is adjusted by the MFCs 241c and 241d, N2 gas is supplied with HCDS gas into the process chamber 201 through the nozzles 249a and 249b, and exhausted through the exhaust pipe 231. FIG. 5A illustrates the wafer 200 at the beginning of the step A1, and FIG. 5B illustrates the wafer 200 supplied with HCDS gas over the entire surface thereof. The HCDS gas is supplied (diffused) from the peripheral portion of the wafer 200 toward the center of the wafer 200.

By supplying HCDS gas to the wafer 200, a silicon-containing layer containing chlorine is formed on the surface of wafer 200, i.e., on concave portion and convex portion of the wafer 200. For example, the silicon-containing layer containing chlorine may be formed by chemical adsorption of HCDS on the surface of the wafer 200 or by thermal decomposition of HCDS. Alternately, the silicon-containing layer containing chlorine may be formed by physical adsorption of HCDS on the surface of the wafer 200. The silicon-containing layer containing chlorine may also be formed by both of chemical adsorption and physical adsorption of HCDS. Hereinafter, the silicon-containing layer containing chlorine may be simply referred to as a silicon-containing layer (Si-containing layer). However, since HCDS gas is supplied from the peripheral portion of the wafer 200 toward the center portion, the thickness distribution of the silicon-containing layer at the surface of the wafer 200 (“thickness distribution of the surface”) is “thickness distribution having thinner center.” That is, the amount of HCDS gas supplied to the wafer 200 is the largest at the peripheral portion of the wafer 200, and gradually decreases toward the center portion of the surface of the wafer 200 due to consumption of HCDS gas. Layer or film formed on the wafer 200 is omitted in FIGS. 5A to 5H for simplification.

### Steps A2 and A3

After the silicon-containing layer is formed on the wafer 200 through the step A1, the valves 243a, 243c, 243d are closed to stop the supply of HCDS gas and the supply of N2 gas into the process chamber 201. With the APC valve 244 open, the vacuum pump 246 vacuum-exhausts the interior of the process chamber 201 to remove the residual HCDS gas from the process chamber 201 through the exhaust pipe 231 (step A2). The HCDS gas remaining on and about the surface of the wafer 200 flows radially outward from the peripheral portion of the wafer 200 and is exhausted through the exhaust pipe 231. FIG. 5C schematically illustrates the amount of the residual HCDS gas in terms of the height of a region denoted as ‘residual HCDS’ with respect to the surface of the wafer 200. The HCDS gas remaining on and about the surface of the wafer 200 is quickly removed from the peripheral portion of the wafer 200, which is shown as dashed lines in FIG. 4. However, HCDS gas is likely to remain in the center portion of the surface of the wafer 200, which is shown as dash-dot lines in FIG. 4. Thus, during the period from the beginning of the step A2 to the completion (saturation) of the exhaust of the residual HCDS gas from the processing chamber 201, the amount of HCDS gas remaining in the center portion of the surface of the wafer 200 is greater than that of HCDS gas remaining in the peripheral portion of the wafer 200. For example, while the HCDS gas remaining in or physically adsorbed to the concave portion at the peripheral portion of the wafer 200 is mostly or completely discharged from the concave portion of the peripheral portion, the HCDS gas remaining in or physically adsorbed to the concave portion at the center portion of the surface of the wafer 200 is mostly not discharged or not discharged at all from the concave portion at the center portion of the surface of the wafer 200 and is retained in the concave portion at the center portion of the surface of the wafer 200. However, components of HCDS gas that are part of the silicon-containing layer formed on the wafer 200 are mostly not removed or not removed at all from both of the concave portions at the center portion and the peripheral portion of the wafer 200 and are retained in both of the concave portions at the center portion and the peripheral portion of the wafer 200. FIG. 5C schematically illustrates the amount of residual HCDS gas, and the actual distribution of the HCDS gas may differ from one shown in FIG. 5C.

After a predetermined time has elapsed from the start of the step A2, the step A3, which is a process for switching from the step A2 to the next step (step B1), is performed. At the time the step B1 starts by performing the step A3, a small amount of HCDS gas remains in the center portion of the surface of the wafer 200 as shown in FIG. 5D. That is, the step A3 is a time period during which the HCDS gas remaining in or physically adsorbed to the concave portion at the center portion of the surface of the wafer 200 is not exhausted to remain in the concave portion and is retained in the concave portion at the center portion of the surface of the wafer 200.

### Step B1

In the step B1, NH₃ gas is supplied to the wafer 200 in the process chamber 201. Specifically, the opening and closing of the valves 243b, 243c and 243d are controlled in the same sequence as those of the step A1. After the flow rate of NH₃ gas is adjusted by the MFC 241b, NH₃ gas is supplied into the process chamber 201 through nozzle 249b. Thereby, the NH₃ gas is supplied onto the wafer 200. FIG. 5D illustrates the wafer at the beginning of the supply of NH₃ gas to the wafer 200, and FIG. 5E illustrates the wafer supplied with NH₃ gas over the entire surface thereof. Similar to HCDS gas, The NH₃ gas is supplied (diffused) from the peripheral portion of the wafer 200 toward the center of the wafer 200.

By supplying NH₃ gas to the wafer 200, at least a portion of the silicon-containing layer formed on the wafer 200 is modified (nitrided). As a result, a layer containing silicon (Si) and nitrogen (N), i.e. a silicon nitride layer, is formed on the wafer 200. Hereinafter, the layer containing silicon (Si) and nitrogen (N) may also be referred to as a modified silicon nitride layer (modified SiN layer). The reaction which modifies (nitrides) the silicon-containing layer is a surface reaction that occurs on the surface of the wafer 200, i.e., on the surface of the concave portion or the convex portion at the surface of the wafer 200. The surface reaction occurs over the entirety of the surface of the wafer 200, i.e., in both the center portion and the peripheral portion of the wafer 200. However, the thickness of the modified SiN layer is likely to have a thickness distribution having thinner center since the thickness of the silicon-containing layer to be modified has a thickness distribution having thinner center as described above, and the amount of NH₃ gas gradually decreases toward the center portion of the surface of the wafer 200 compared to the peripheral portion of the wafer 200 toward which NH₃ gas is supplied first.

Also, by supplying NH₃ gas to the wafer 200, the center portion of the surface of the wafer 200 may be mixed to cause a vapor phase reaction (CVD reaction) between the HCDS gas remaining in the center portion of the surface of the wafer 200 and NH₃ gas supplied to the wafer 200. For example, a physically adsorbed HCDS gas in the concave portion at the center portion of the surface of the wafer 200 may undergo a vapor phase reaction with NH₃ gas supplied to the wafer 200. As a result, a material (SiN) containing silicon from the HCDS and nitrogen from NH₃ is deposited (formed) at the center portion of the surface of the wafer 200 to form a SiN layer. Hereinafter, the SiN layer formed by deposition is also referred to as “deposited SiN layer.” The vapor phase reaction occurs mainly in the center portion of the surface of the wafer 200, and hardly occurs or does not occur at all in portions (e.g. the peripheral portion) other than the center portion of the surface of the wafer 200. Thus, the thickness of the deposited SiN layer formed by performing the step B1 has the thickness distribution having thicker center.

Accordingly, a SiN layer (hereinafter also referred to as “laminated SiN layer”) in which the modified SiN layer and the deposited SiN layer are laminated is formed on the wafer 200. The thickness distribution of the laminated SiN layer is a sum of “thickness distribution having thinner center” of the modified SiN layer and “thickness distribution having thicker center” of the deposited SiN layer. By increasing the ratio of the thickness of the deposited SiN layer to the thickness of the modified SiN layer (deposited SiN layer/modified SiN layer), that is, by increasing the amount of HCDS gas remaining in the center portion of the surface of the wafer 200, the thickness distribution of the laminated SiN layer may be changed from “thickness distribution having thinner center” to “flat distribution” or “thickness distribution having thicker center” or the center portion of the laminated SiN layer may be further thickened. By lowering the ratio, that is, by decreasing the amount of HCDS gas remaining in the center portion of the surface of the wafer 200, the thickness distribution of the laminated SiN layer may be changed from “thickness distribution having thicker center” to “flat distribution” or “thickness distribution having thinner center” or the center portion of the laminated SiN layer may be further thinned.

Since the modified SiN layer and the deposited SiN layer are both made of SiN, and are formed under the same environment and exposed to the same environment, the laminated SiN layer formed by stacking of the modified SiN layer and the deposited SiN layer is inseparable throughout the entirety of the surface of the wafer 200. In addition, the laminated SiN layer is a high-quality layer with few impurities such as chlorine (Cl). This is because the impurities such as chlorine (Cl) contained in the silicon-containing layer are separated from the silicon-containing layer during the surface reaction when the modified SiN layer is formed, and chlorine (Cl) contained in HCDS gas is separated from silicon (Si) during the vapor phase reaction such that chlorine (Cl) does not penetrate into the deposited SiN layer.

### Steps B2 and B3

After the deposited SiN layer is formed on the wafer 200 through the step B1, the valves 243b, 243c, 243d are closed to stop the supply of NH₃ gas and the supply of N2 gas into the process chamber 201. With the APC valve 244 open, the vacuum pump 246 vacuum-exhausts the interior of the process chamber 201 to remove the residual NH₃ gas from the process chamber 201 through the exhaust pipe 231 (step B2). The NH₃ gas remaining on and about the surface of the wafer 200 flows radially outward from the peripheral portion of the wafer 200 and is exhausted through the exhaust pipe 231. Similar to FIG. 5C, FIG. 5F schematically illustrates the amount of the residual NH₃ gas in terms of the height of a region denoted as ‘residual NH₃’ with respect to the surface of the wafer 200. The NH₃ gas remaining on and about the surface of the wafer 200 is quickly removed from the peripheral portion of the wafer 200, which is shown as dashed lines in FIG. 4. However, NH₃ gas is likely to remain in the center portion of the surface of the wafer 200, which is shown as dash-dot lines in FIG. 4. Thus, during the period from the beginning of the step B2 to the completion (saturation) of the exhaust of the residual NH₃ gas from the processing chamber 201, the amount of NH₃ gas remaining in the center portion of the surface of the wafer 200 is greater than that of NH₃ gas remaining in the peripheral portion of the wafer 200. For example, while the NH₃ gas remaining in or physically adsorbed to the concave portion at the peripheral portion of the wafer 200 is mostly or completely discharged from the concave portion of the peripheral portion, the NH₃ gas remaining in or physically adsorbed to the concave portion at the center portion of the surface of the wafer 200 is mostly not discharged or not discharged at all from the concave portion at the center portion of the surface of the wafer 200 and is retained in the concave portion at the center portion of the surface of the wafer 200. The inventors of the present application found by research that NH₃ gas is more likely to remain on the surface of the wafer 200 than HCDS gas.

After a predetermined time has elapsed from the start of the step B2, the step B3, which is a process for switching from the step B2 to the next step (i.e. the step A1 of the second cycle), is performed. At the time the step B1 starts by performing the step B3, a small amount of NH₃ gas remains in the center portion of the surface of the wafer 200 as shown in FIG. 5G. That is, the step B3 is a time period during which the NH₃ gas remaining in or physically adsorbed to the concave portion at the center portion of the surface of the wafer 200 is not exhausted to retain in the concave portion.

### Step A1

As shown in FIG. 5G, the supply of HCDS gas to the wafer 200 is started (the step A1 of the second cycle) with NH₃ gas remaining in the center portion of the surface of the wafer 200 after the step B3 of the first cycle is performed. As shown in FIG. 5H, HCDS gas is supplied to the entirety of the surface of the wafer 200 with the NH₃ gas remaining in the center portion of the surface of the wafer 200 (the step A1 the second cycle) as predetermined time elapses. Similar to the step A1 of the first cycle, a silicon-containing layer is formed on the surface of the wafer 200 in the step A1 of the second cycle. The thickness distribution of the silicon-containing layer formed in the step A1 of the second cycle is similar to the thickness distribution of the silicon-containing layer formed in the step A1 of the first cycle, which is thickness distribution having thinner center.

In the step A1 of the second cycle, NH₃ gas remaining in the center portion of the surface of the wafer 200 is mixed to cause a vapor phase reaction with HCDS gas supplied to the wafer 200. For example, the NH₃ gas floating in or physically adsorbed to the concave portion in the center portion of the surface of the wafer 200 may be mixed to cause the vapor phase reaction with HCDS gas supplied to the wafer 200. A material (SiN) containing silicon from the HCDS and nitrogen from NH₃ is deposited at the center portion of the surface of the wafer 200 to form a SiN layer, which is referred to as “deposited SiN layer” similar to the step B1. Similar to the vapor phase reaction in the step B1, the vapor phase reaction in the step A1 of the second cycle occurs mainly in the center portion of the surface of the wafer 200, and hardly occurs or does not occur at all in portions (e.g. the peripheral portion) other than the center portion of the surface of the wafer 200. Thus, similar to the deposited SiN layer formed in the step B1, the thickness of the deposited SiN layer formed by performing the step A1 of the second cycle has the thickness distribution having thicker center.

Thereafter, the laminated SiN layer including the laminated structure of the modified SiN layer and the deposited SiN layer is formed on the wafer 200 by performing the steps A2, A3 and B1 through B3 in the same manner as described above, i.e., by performing the second cycle. Similar to the deposited SiN layer formed by performing the first cycle, the laminated SiN layer is inseparable throughout the entirety of the surface of the wafer 200, and is a high-quality layer with few impurities. In addition, compared to the laminated SiN layer formed by performing the first cycle, the laminated SiN layer formed by the second cycle or any cycle after the second cycle has a thicker center. This is because the deposited SiN layer is formed in the steps A1 as well as the step B1.

### Performing Predetermined Number of Times

As described above, the cycle including the steps A1 through A3 and B1 through B3 is performed one or more times (n times) wherein the steps A1 through A3 and B1 through B3 are sequentially performed and the steps A1, A2, B1 and B2 and non-simultaneously performed to form SiN film having a desired thickness distribution on the wafer 200. It is preferable that the cycle is repeated a plurality of times. That is, it is preferable that the laminated SiN layer having a desired thickness is formed by laminating SiN layers thinner than the desired thickness by repeating the cycle a plurality of times until the desired thickness obtained.

For example, the processing conditions of the step A1 are as follows:

The flow rate of HCDS gas: 10 sccm to 2,000 sccm, preferably 100 sccm to 1,000 sccm;

The time duration of HCDS gas supply: 1 second to 120 seconds, preferably 1 second to 60 seconds;

The flow rate of N2 gas (for each gas supply pipe): 10 sccm to 10,000 sccm;

The film-forming temperature: 250° C. to 800° C., preferably 400° C. to 700° C.; and

The film-forming pressure: 1 Pa to 2,666 Pa, preferably 67 Pa to 1,333 Pa.

For example, the processing conditions of the step A2 are as follows:

The time duration of exhaust (from the beginning to the end of the step A2): 1 second to 30 seconds, preferably 1 second to 10 seconds; and

Pressure: 50 Pa to 2,000 Pa, preferably 100 Pa to 1,000 Pa.

For example, the processing conditions of the step B1 are as follows:

The flow rate of NH₃ gas: 1 sccm to 4,000 sccm, preferably 1 sccm to 3,000 sccm;

The time duration of NH₃ gas supply: 1 second to 120 seconds, preferably 1 second to 60 seconds;

The flow rates of N₂ gas (for each gas supply pipe): 10 sccm to 10,000 sccm;

The film-forming temperature: the same as that of the step A1; and

The film-forming pressure: 1 Pa to 4,000 Pa, preferably 1 Pa to 3,000 Pa.

For example, the processing conditions of the step B2 are as follows:

The time duration of exhaust (from the beginning to the end of the step B2): 1 second to 30 seconds, preferably from 1 second to 10 seconds; and

Pressure: 50 Pa to 2,000 Pa, preferably from 100 Pa to 1,000 Pa.

Instead of HCDS gas, chlorosilane-based gases such as monochlorosilane (SiH₃Cl, abbreviated as MCS) gas, dichlorosilane (SiH₂Cl₂, abbreviated as DCS) gas, trichlorosilane (SiHCl₃, abbreviated as TCS) gas, tetrachlorosilane (SiCl₄, abbreviated as STC) gas and octachlorotrisilane (Si₃Cl₈, abbreviated as OCTS) gas may be used as the source.

Instead of NH₃ gas, hydrogen nitride-based gases such as diazene (N₂H₂) gas, hydrazine (N₂H₄) gas and N₃H₈ gas may be used as the reactant.

Instead of N₂ gas, rare gases such as argon (Ar) gas, helium (He) gas, neon (Ne) gas and xenon (Xe) gas may be used as the inert gas.

### Purging and Returning to Atmospheric Pressure Step

After the film having a desired composition and a desired thickness is formed on the wafers 200, N₂ gas is supplied into the process chamber 201 through each of the nozzles 249a and 249b and then exhausted through the exhaust pipe 231. The process chamber 201 is thereby purged such that the gas or the reaction by-products remaining in the process chamber 201 are removed from the process chamber 201 (purging). Thereafter, the inner atmosphere of the process chamber 201 is replaced with an inert gas (substitution by inert gas), and the inner pressure of the process chamber 201 is returned to atmospheric pressure (returning to atmospheric pressure).

### Boat Unloading and Wafer Discharging Step

Then, the seal cap 219 is lowered by the boat elevator 115 and the lower end of the reaction tube 203 is opened. The boat 217 with the processed wafers 200 charged therein is unloaded from the reaction tube 203 through the lower end of the reaction tube 203 (boat unloading). The processed wafers 200 are discharged from the boat 217 (wafer discharging).

### Effects of the Embodiment

One or more advantageous effects described below are provided according to the embodiment.

(a) By performing the step A3, the center portion of the surface of the wafer 200 is mixed to cause the vapor phase reaction when performing the next step B1. Thus, the SiN film having the desired thickness distribution, e.g. flat distribution or thickness distribution having thicker center may be formed on the wafer 200 which is a patterned wafer.

(b) By performing step B3, the center portion of the surface of the wafer 200 is mixed to cause the vapor phase reaction when performing the next step A1. Thus, the SiN film having the desired thickness distribution, e.g. flat distribution or thickness distribution having thicker center may be formed on the wafer 200 which is a patterned wafer.

(c) By stopping the supply of N₂ gas into the process chamber 201, i.e. by stopping the supply of N₂ gas acting as a purge gas, HCDS gas or NH₃ gas may be reliably remaining in the center portion of the surface of the substrate when performing the steps A2 and B2. As a result, the above-described effects (a) and (b) are securely obtained.

(d) The above-described effects may also be obtained when sources other than HCDS gas, reactants other than NH₃ gas and inert gas other than N₂ gas are used.

### (4) MODIFIED EXAMPLES

The film-forming process according to the embodiment may be modified as in the modified examples described below.

### First Modified Example

Instead of performing both of the steps A3 and B3, only one of the steps A3 and B3 may be performed. For example, the step A2 may be performed continuously until HCDS gas does not remain in the center portion of the surface of wafer 200 in case the step A3 is not performed. Alternately, the step B2 may be performed continuously until NH₃ gas does not remain in the center portion of the surface of wafer 200 in case the step B3 is not performed.

Moreover, the steps A3 and B3 may be performed once in plurality of cycles instead of every cycle.

In addition, when the step A3 is performed, HCDS gas may remain in the peripheral portion of the surface of the wafer 200 as well as the center portion of the surface of the wafer 200. That is, while the HCDS gas may remain throughout the surface of the wafer 200, the amount of HCDS gas remaining in the center portion of the wafer 200 surface may be greater than the amount of HCDS gas remaining in the peripheral portion of the wafer 200. Also, when the step B3 is performed, NH₃ gas may remain in the peripheral portion of the surface of the wafer 200 as well as the center portion of the surface of the wafer 200. That is, while the NH₃ gas may remain throughout the surface of the wafer 200, the amount of NH₃ gas remaining in the center portion of the wafer 200 surface may be greater than the amount of NH₃ gas remaining in the peripheral portion of the wafer 200.

The effects of the first modified example are the same as those of the film-forming sequence shown in FIG. 4. In addition, the first modified example further provides the effect of facilitating the decrease in thickness of the center portion of the SiN film to reduce the thickness distribution having thicker center in addition to the effects of the film-forming sequence shown in FIG. 4.

### Second Modified Example

By maintaining the valves 243c and 243d open while performing the steps A2 and B2, N₂ gas may be continuously supplied into the process chamber 201. Since N₂ gas acts as a purge gas, the efficiency of exhausting HCDS gas or NH₃ gas from the process chamber 201 is improved and the time required for performing the steps A2 and B2 may be shortened. However, it is preferable that the flow rate (or flow velocity) of N₂ gas supplied through the nozzles 249a and 249b is controlled by the wafer 200 such that N₂ gas does not reach the center portion of the surface of the wafer 200 in order to securely remain HCDS gas or NH₃ gas in the center portion of the surface of the wafer 200. For example, the flow rate of the N₂ gas supplied through each of the nozzles 249a and 249b may range from 1 sccm to 3,000 sccm, preferably from 1 sccm to 2,000 sccm. Further, the above-mentioned “N₂ gas does not reach the center portion” means “only extremely small amount of N₂ gas reaches the center portion” as well as “N₂ gas does not reach the center portion at all.” When the amount of HCDS gas or NH₃ gas reaching the center portion of the surface of the wafer 200 is extremely small (or when the flow rate is extremely small), remaining HCDS gas or NH₃ gas in the center portion of the surface of the wafer 200 is facilitated. The second modified example provides effects the same as those of the film-forming sequence shown in FIG. 4.

### Third Modified Example

When the steps A2 and B2 are performed, the inner pressure of the process chamber 201 is relatively high, for example, ranging from 100 Pa to 1,000 Pa. That is, by decreasing the opening degree of the APC valve 244, the exhaust rate may be reduced. In addition, the spacing (pitch) between the wafers 200 supported by the boat 217 may be reduced to lower the conductance of the wafer arrangement region. In this case, although the exhaust efficiencies of HCDS gas and NH₃ gas in steps A2 and B2, respectively, are lowered, remaining HCDS gas or NH₃ gas in the center portion of the wafer 200 surface is facilitated. The third modified example provides effects the same as those of the film-forming sequence shown in FIG. 4.

### Other Embodiments

While the technique is described by way of the above-described embodiment, the above-described technique is not limited thereto. The above-described technique may be modified in various ways without departing from the gist thereof.

For example, the above-described technique may be applied to the formations of films such as a silicon oxynitride film (SiON film), a silicon carbonitride film (SiCN film), a silicon oxycarbonitride film (SiOCN film), a silicoboron carbonitride film (SiBCN film), a silicoboron nitride film (SiBN film) and a silicon oxide film (SiO film). Chlorosilane-based gas such as HCDS gas and aminosilane-based gas such as bis(diethylamino)silane (SiH₂[N(C₂H₅)₂]₂, abbreviated as BDEAS) gas, for example, may be used as the source when forming these films. A nitriding gas such as NH₃ gas, an oxidizing gas such as oxygen (O₂) gas, a carbon-containing gas such as propylene (C₃H₆) gas, a gas containing carbon and nitrogen such as triethylamine ((C₂H₅)₃N, abbreviated as TEA) gas, a oxidizing gas such as a plasma-excited oxygen gas (O₂*) and a boron-containing gas such as trichloroborane (BCl₃) gas, for example, may be used as the reactant when forming these films according to the film-forming sequences described below. The film-forming sequences described below may be performed according to the processing sequences and the processing conditions same as those of the above-described embodiment, and the same effects may be obtained.

(HCDS→P₁→NH₃→P₂→O₂→P₃)×n→SiON

(HCDS→P₁→C₃H₆→P₂→NH₃→P₃)×n→SiCN

(HCDS→P₁→TEA→P₂→O₂→P₃)×n→SiOC(N)

(HCDS→P₁→C₃H₆→P₂→NH₃→P₃→O₂→P₄)×n→SiOC(N)

(HCDS→P₁→C₃H₆→P₂→BCl₃→P₃→NH₃→P₄)×n→SiBCN

(HCDS→P₁→BCl₃→P₂→NH₃→P₃)×n→SiBN

(BDEAS→P₁→O₂*→P₂)×n→SiO

For example, the above-described technique may be applied to the formation of metal-based films such as a titanium nitride film (TiN film), a titanium aluminum carbide film (TiAlC film), a titanium aluminum carbonitride film (TiAlCN film), an aluminum nitride film (AlN film) and a titanium oxide film (TiO film). Gases such as titanium tetrachloride (TiCl₄) gas and trimethylaluminum (Al(CH₃)₃, abbreviated as TMA) gas, for example, may be used as the source when forming these films. A nitriding gas such as NH₃ gas and an oxidizing gas such as water vapor (H₂O), for example, may be used as the reactant when forming the metal-based films according to the film-forming sequences described below. The film-forming sequences of described below may be performed according to the processing sequences and the processing conditions same as those of the above-described embodiment, and the same effects may be obtained.

(TiCl₄→P₁→NH₃→P₂)×n→TiN

(TiCl₄→P₁→TMA→P₂)×n→TiAlC

(TiCl₄→P₁→TMA→P₂→NH₃→P₃)×n→TiAlCN

(TMA→P₁→NH₃→P₂)×n→AlN

(TiCl₄→P₁→H₂O→P₂)×n→TiO

The recipe used for substrate processing is preferably prepared individually according to the processing contents and is stored in the memory device 121c via an electric communication line or the external memory device 123. When starting the substrate processing, the CPU 121a preferably selects an appropriate recipe among the plurality of recipe stored in the memory device 121c according to the contents of the substrate processing. Thus, various films having different composition ratios, different qualities and different thicknesses may be formed at high reproducibility using a single substrate processing apparatus. Further, since the burden on the operator may be reduced, various processes may be performed quickly while avoiding a malfunction of the apparatus.

The above-described recipe is not limited to creating a new recipe. For example, the recipe may be prepared by changing an existing recipe stored in the substrate processing apparatus in advance. When changing the existing recipe to a new recipe, the new recipe may be installed in the substrate processing apparatus via the telecommunication line or the recording medium in which the new recipe is stored. The existing recipe already stored in the substrate processing apparatus may be directly changed to a new recipe by operating the I/O device 122 of the substrate processing apparatus.

While a batch type substrate processing apparatus capable of simultaneously processing plurality of substrates to form the film is exemplified in the above-described embodiment, the above-described technique is not limited thereto. For example, the above-described technique may be applied to the film formation using a single type substrate processing apparatus capable of processing a substrate. While a substrate processing apparatus having hot wall type processing furnace is exemplified in the above-described embodiment, the above-described technique is not limited thereto. For example, the above-described technique may be applied the film formation using a substrate processing apparatus having cold wall type processing furnace.

The film formation may be performed according to the processing sequences and the processing conditions same as those of the above-described embodiments and modified examples using these substrate processing apparatuses, and the same effects may be obtained.

The above-described embodiments and the modified examples may be appropriately combined. The processing sequences and the processing conditions of the combinations may be substantially the same as those of the above-described embodiment.

Films such as the SiN film formed in accordance with the above-described embodiment or modified examples may be widely used, for example, as an insulating film, a spacer film, a mask film, a charge storage film and a stress control film. As the semiconductor device is miniaturized, the film formed on the surface of the wafer is required to have a more uniform thickness. According to the above-described technique, for example, a film having a flat distribution may be formed on a patterned wafer having a high-density pattern thereon. Therefore, according to the above-described technology, a film having a more uniform thickness may be formed on the surface of the wafer.

### Results of Experiments

The results of experiments supporting the effects of the above-described embodiments will be described below.

In the experiment, the SiN film was formed on the wafer using the substrate processing apparatus shown in FIG. 1 and the film-forming sequence shown in FIG. 4. A bare wafer with no pattern on the surface thereof and a patterned wafer with patterns on the surface thereof were used. The surface area of the patterned wafer was 10 to 15 times larger than that of the bare wafer. The processing conditions were the same as the processing conditions described in the above embodiment. The film-forming processes for the bare wafer and the patterned wafer were performed simultaneously in the same process chamber.

The thickness distribution of the SiN film formed on the patterned wafer was “flat distribution” or “thickness distribution having thicker center” wherein the SiN film is thicker at the center portion thereof and thinner at the peripheral portion thereof. That is, the SiN film formed on the patterned wafer was found to be thicker at the center portion thereof compared to the SiN film formed on the bare wafer. The reason is that the uneven structure at the center portion of the patterned wafer facilitates remaining of HCDS gas and NH₃ gas in the center portion of the patterned wafer compared to the bare wafer without the uneven structure at the center portion thereof. It is found that the thickness distribution of the SiN film formed on the wafer may be controlled to be a desired distribution by adjusting the processing conditions of the steps A2 and B2 or the timing of the steps A3 and B3.

According to the technique described herein, the thickness distribution of the film formed on the surface of the substrate may be controlled.

What is claimed is:

1. A method of manufacturing a semiconductor device, comprising:
forming a film on a substrate by performing a cycle a predetermined number of times, the cycle comprising:
(a) supplying a source to the substrate accommodated in a process chamber;
(b) exhausting the source from the process chamber;
(c) supplying a reactant to the substrate accommodated in the process chamber; and
(d) exhausting the reactant from the process chamber,
wherein (a) through (d) are performed non-simultaneously, and the cycle further comprises at least one of:
(e) starting a next step with the source remaining in a center portion of a surface of the substrate after a first predetermined time elapses from a start of (b); and
(f) starting a next step with the reactant remaining in the center portion of the surface of the substrate after a second predetermined time elapses from a start of (d).

2. The method of claim 1, wherein the cycle is repeated, and each cycle comprises (f).

3. The method of claim 1, wherein the cycle is repeated, and each cycle comprises (e).

4. The method of claim 1, wherein an inner atmosphere of the process chamber is exhausted outward and radially from a peripheral portion of the substrate at least in one of (b) and (d).

5. The method of claim 1, wherein the source and reactant are supplied from a peripheral portion of the substrate toward the center portion of the surface of the substrate in (a) and (c), respectively.

6. The method of claim 1, wherein a purge gas is supplied into the process chamber in at least one of (b) and (d) at a flow rate such that the purge gas does not reach the center portion of the surface of the substrate.

7. The method of claim 1, wherein an atmosphere remaining in the process chamber is exhausted at an exhaust rate in at least one of (b) and (d) such that an amount of the atmosphere remaining in the center portion of the surface of the substrate is greater than that of the atmosphere remaining in the peripheral portion of the surface of the substrate.

8. The method of claim 1, wherein the substrate comprises a concave portion on the surface thereof, and the source and the reactant remaining in the concave portion at the center portion of the surface of the substrate are retained without being exhausted in (e) and (f), respectively.

9. The method of claim 8, wherein the source and the reactant physically adsorbed to a surface of the concave portion at the center portion of the surface of the substrate are retained without being exhausted in (e) and (f), respectively.

10. The method of claim 8, wherein the source remaining in the concave portion at the center portion of the surface of the substrate is mixed with the reactant supplied to the substrate to cause a vapor phase reaction when (c) is performed after (e), and the reactant remaining in the concave portion at the center portion of the surface of the substrate is mixed with the source supplied to the substrate to cause a vapor phase reaction when (a) is performed after (f).

11. The method of claim 10, wherein the vapor phase reaction is caused in the center portion of the surface of the substrate and a layer formed on a portion of the surface other than the center portion is subjected to a surface reaction with the reactant when (c) is performed after (e), and
wherein the vapor phase reaction is caused in the center portion of the surface of the substrate and the layer is formed on the portion of the surface other than the center portion when (a) is performed after (f).

12. The method of claim 1, wherein the source remaining in the center portion of the surface of the substrate is subjected to a vapor phase reaction with the reactant supplied to the substrate to form a layer containing a first element contained in the source and a second element contained in the reactant by depositing a material containing the first element and the second element and a layer containing the first element formed on a portion of the surface other than the center portion is modified to the layer containing the first element and the second element by reacting with the reactant supplied to the substrate when (c) is performed after (e).

13. The method of claim 1, wherein the source remaining in the center portion of the surface of the substrate is subjected to a vapor phase reaction with the reactant supplied to the substrate to form a layer containing a first element contained in the source and a second element contained in the reactant by depositing a material containing the first element and the second element and a layer containing the first element is formed on a portion of the surface other than the center portion when (a) is performed after (f).

14. A substrate processing apparatus comprising:
a process chamber where a substrate is processed;
a source supply system configured to supply a source to the substrate accommodated in the process chamber;
a reactant supply system configured to supply a reactant to the substrate accommodated in the process chamber;
an exhaust system configured to exhaust an inside of the process chamber; and
a controller configured to control the source supply system, the reactant supply system and the exhaust system to perform: forming a film on a substrate by performing a cycle a predetermined number of times, the cycle comprising: (a) supplying the source to the substrate accommodated in the process chamber; (b) exhausting the source from the process chamber; (c) supplying the reactant to the substrate accommodated in the process chamber; and (d) exhausting the reactant from the process chamber, wherein (a) through (d) are performed non-simultaneously, and the cycle further comprises at least one of: (e) starting a next step with the source remaining in a center portion of a surface of the substrate after a first predetermined time elapses from a start of (b); and (f) starting a next step with the reactant remaining in the center portion of the surface of the substrate after a second predetermined time elapses from a start of (d).

15. A non-transitory computer-readable recording medium storing a program that causes, by a computer, a substrate processing apparatus to perform: forming a film on a substrate by performing a cycle a predetermined number of times, the cycle comprising:
(a) supplying a source to the substrate accommodated in a process chamber;
(b) exhausting the source from the process chamber;
(c) supplying a reactant to the substrate accommodated in the process chamber; and
(d) exhausting the reactant from the process chamber,
wherein (a) through (d) are performed non-simultaneously, and the cycle further comprises at least one of:
(e) starting a next step with the source remaining in a center portion of a surface of the substrate after a first predetermined time elapses from a start of (b); and
(f) starting a next step with the reactant remaining in the center portion of the surface of the substrate after a second predetermined time elapses from a start of (d).
